(19) United States
(12) Patent Application Publication
(10) Pub. No.: US 2008/0061842 A1
(43) Pub. Date: Mar. 13, 2008

(54) Circuit and method for detecting timed amplitude reduction of a signal relative to a threshold voltage

(75) Inventors: Milam Paraschou, Eden Prairie, MN (US); Robert L. Rabe, Chanhassen, MN (US)

Correspondence Address: Edward W. Bulchis, Esq.;DORSEY & WHITNEY LLP, Suite 3400, 1420 Fifth Avenue, Seattle, WA, 98101, US

(73) Assignee: Micron Technology, Inc.

(21) Appl. No.: 11/518,140

(22) Filed: Sep. 7, 2006

(51) Int. Cl. H03K 5/22

(52) U.S. Cl. 327/77

(57) ABSTRACT

A signal amplitude threshold detector includes a comparator having first and second inputs. An input signal is coupled to the first input of the comparator. The second input of the comparator receives a reference voltage from a reference voltage generator. The signal amplitude threshold detector also includes a parallel combination of a capacitor and a resistor coupled between the first input of the comparator and ground. The comparator generates a first logic level when the amplitude of the input signal is less than the amplitude of the reference voltage, and it generates a second logic level when the amplitude of the input signal is greater than the amplitude of the reference voltage. The input signal may be supplied by a peak voltage detector, which supplies current to the capacitor when the peak amplitude of a signal is greater than the voltage on the capacitor.

### TECHNICAL FIELD

This invention relates to digital and analog circuits, and, more particularly, to a circuit and method for detecting the peak value of a signal and the reduction of the signal from the peak value after a predetermined time.

### BACKGROUND OF THE INVENTION

It is important in a large variety of electrical devices to be able to detect if the amplitude of a digital or analog signal has exceeded a predetermined value. For example, it may be necessary to determine if a signal is present or to recognize if a signal that is present has a amplitude exceeding a threshold, such as a value corresponding to a specific logic level. Voltage threshold circuits operable to determine if the amplitude of a digital or analog signal has exceeded a predetermined threshold are well known in the art, and they are used in a wide variety of applications.

It is important in some applications to be able to do more than simply determine if an analog or digital signal is above or below a specific voltage threshold. In some cases, for example, it is important to determine if an analog or digital signal has fallen below a threshold voltage for more than a predetermined period. Yet, conventional amplitude detection circuits are generally able to provide information only about the amplitude characteristics of the analog or digital signal. These amplitude detection circuits are generally not able to provide information about time-related characteristics of the analog or digital signal, such as when the signal has fallen below a threshold voltage and remained there for longer than a predetermine period.

There is therefore a need for a circuit and method that can not only detect when the amplitude of an analog or digital signal has exceeded a threshold amplitude, but can also determine when the signal has remained below the threshold amplitude for longer than a predetermine period.

### SUMMARY OF THE INVENTION

A signal amplitude threshold circuit and method generates an output signal indicative of an input signal exceeding a predetermined threshold. A comparator has a first input receiving a reference voltage and a second input receiving a first signal that varies as a function of the amplitude of the input signal. The amplitude of the first signal applied to the second input quickly increases when the amplitude of the input signal increases above the amplitude of the first signal. As a result, the amplitude of the first signal is increased to substantially the amplitude of the input signal. When the amplitude of the input signal decreases below the amplitude of the first signal, the amplitude of the first signal is slowly decreased. The first signal may be generated across the parallel combination of a resistor and capacitor. In such case, the capacitor may be quickly charged with a current to increase the first signal when the amplitude of the input signal increases above the amplitude of the first signal. The capacitor may be slowly discharged by the resistor when the amplitude of the input signal decreases below the amplitude of the first signal.

### BRIEF DESCRIPTION OF THE DRAWINGS

FIG. 1 is a schematic diagram of a signal amplitude threshold detector according to one example of the invention.

FIG. 2 is a schematic diagram of a signal amplitude threshold detector according to another example of the invention.

FIG. 3 is a block diagram of a computer system having a system memory that uses a plurality of memory hub memory modules, each of which use the signal amplitude threshold detector of FIG. 1 or 2 or a signal amplitude threshold detector according to some other example of the invention.

FIG. 4 is a block diagram of a memory hub used in each of the memory hub modules shown in FIG. 3 according to one example of the invention.

### DETAILED DESCRIPTION OF THE INVENTION

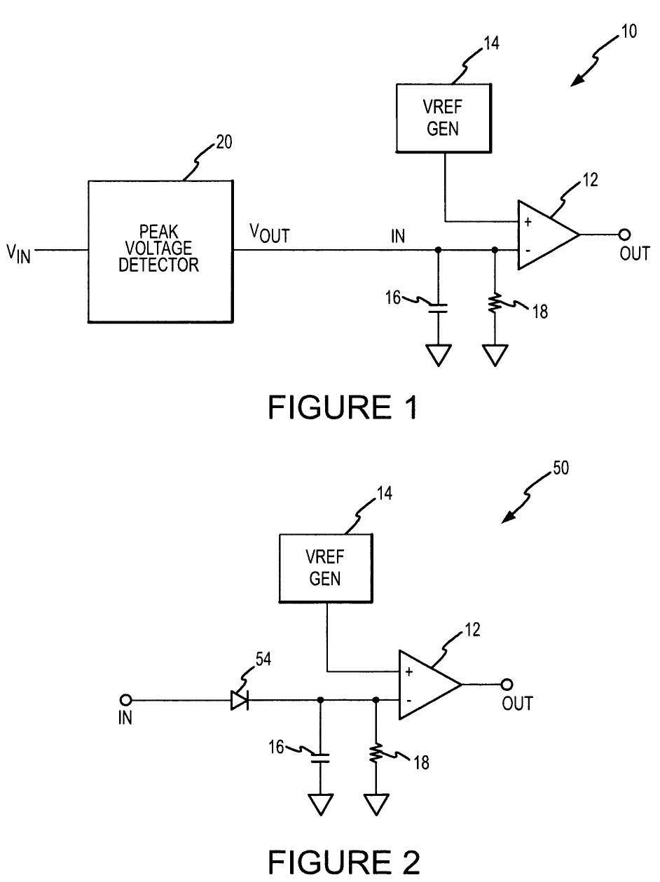

A signal amplitude threshold detector 10 according to one example of the invention is shown in FIG. 1 in the context of being used with a peak voltage detector 20. However, it will be understood that it may be used in other contexts in a wide variety of applications. The peak voltage detector 20 receives an input voltage V_{IN} and outputs a signal V_{OUT} having an amplitude that is indicative of the peak amplitude of the signal V_{IN}. The V_{OUT} signal is used as an input signal IN to the signal amplitude threshold detector 10. As explained in greater detail below, the threshold detector 10 outputs a signal OUT that transitions from a first logic level to a second logic level when the amplitude of VIN exceeds a threshold amplitude. However, the signal OUT does not transition back to the first logic level until the amplitude of IN has fallen below the threshold amplitude and has remained below the threshold amplitude for more than a predetermined period.

With further reference to FIG. 1, the signal amplitude threshold detector 10 includes a comparator 12 having a “−” input to which the signal V_{OUT} from the output of the peak voltage detector 20 is applied. A “+” input of the comparator 12 receives a reference voltage V_{REF} from a reference voltage generator 14, which sets a threshold level for the amplitude of the IN signal. The parallel combination of a capacitor 16 and a resistor 18 are connected between ground and the “−” input to which the signal IN signal is applied.

In operation, when the voltage of the IN signal is less than the reference voltage V_{REF}, the output of the comparator 12 is high. Conversely, when the IN voltage is greater than the reference voltage V_{REF}, the output of the comparator 12 is low. The peak voltage detector 20 quickly charges the capacitor 16 to a voltage corresponding to the peak amplitude of the signal V_{IN}. However, the peak voltage detector 20 does not discharge the capacitor 16 when the peak amplitude of the signal VIN subsequently drops. Instead, the peak voltage detector 20 simply stops supplying current to the capacitor 16, thereby allowing the capacitor 16 to discharge through the resistor 18. The peak voltage detector 20 may be, for example, a peak voltage detector described in U.S. patent application Ser. No. entitled “ABSOLUTE VALUE PEAK DIFFERENTIAL VOLTAGE DETECTOR CIRCUIT AND METHOD” of which the inventor is a co-inventor, which is incorporated by reference herein. The rate at which the capacitor 16 discharges is a function of the product of the resistor 18 and the value of the capacitor 16. Thus, the signal OUT transitions low almost as soon as the amplitude of the signal V_{IN} increases. However, the time required for the signal OUT to transition high after the amplitude of V_{IN} decreases depends on the peak amplitude of the V_{IN} signal and the length of time the amplitude of V_{IN} is at its reduced value. The OUT signals provided by the signal amplitude threshold detector 10 is thus indicative of not only the amplitude of the V_{IN} signal, but also provides an indication of the V_{IN} signal remaining below the threshold amplitude for longer than a predetermined period.

A signal amplitude threshold detector 50 according to another example of the invention is shown in FIG. 2. The detector 50 uses most of the same components that are used in the signal amplitude threshold detector 10 of FIG. 1. Therefore, in the interest of brevity, these common components have been provided with the same reference numerals, and an explanation of their structure and operation will not be repeated. The signal amplitude threshold detector 50 differs from the detector 10 shown in FIG. 1 by coupling the input signal IN to the comparator 12 through a diode 54. As a result, the capacitor 16 is quickly charged to the voltage of the signal V_{IN} less the voltage drop across the diode 54. When the amplitude of V_{IN} subsequently drops, the diode 54 becomes backed-biased, thereby allowing the capacitor 16 to discharge to the amplitude of VIN less the voltage drop across the diode 54. If the amplitude of V_{IN} less the voltage drop across the diode 54 falls below the reference voltage V_{REF}, the signal OUT at the output of the comparator 12 will transition high. Again, the amount of time required for the OUT signal to transition high will depend upon the voltage to which the capacitor 16 was charged and the amount of time the voltage V_{IN} is at its reduced amplitude.

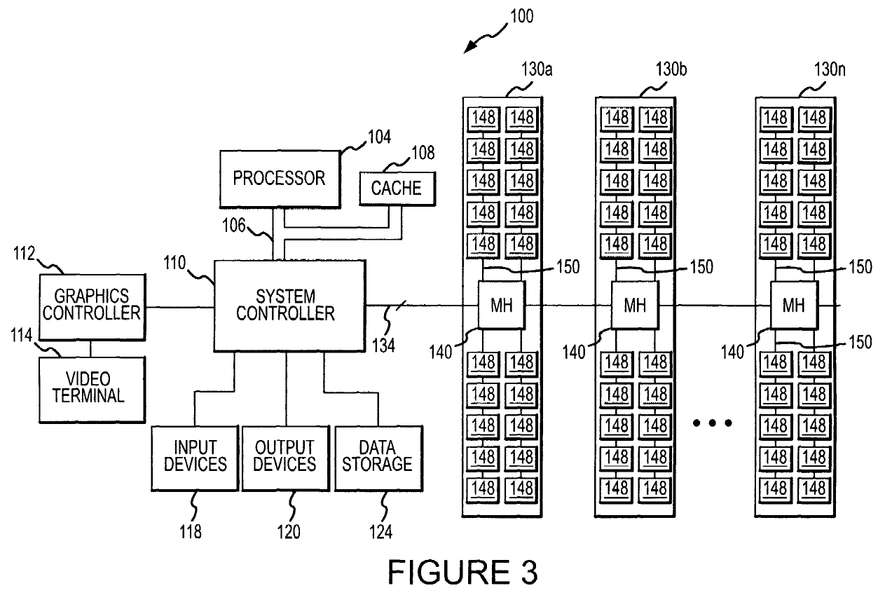

A signal amplitude threshold detector 10 according to various examples of the invention, including the signal amplitude threshold detector 10 used with the peak detector 20 shown in FIG. 1, can be used for a variety of purposes in a wide variety of electronic devices. For example, a signal amplitude threshold detector 10 and peak detector 20 according to one example of the invention can be used in a computer system 100 as shown in FIG. 3. The computer system 100 includes a processor 104 for performing various computing functions, such as executing specific software to perform specific calculations or tasks. The processor 104 includes a processor bus 106 that normally includes an address bus, a control bus, and a data bus. The processor bus 106 is typically coupled to cache memory 108, which, as previously mentioned, is usually static random access memory (“SRAM”). Finally, the processor bus 106 is coupled to a system controller 110, which is also sometimes referred to as a “North Bridge” or “memory controller.”

The system controller 110 serves as a communications path to the processor 104 for a variety of other components. More specifically, the system controller 110 includes a graphics port that is typically coupled to a graphics controller 112, which is, in turn, coupled to a video terminal 114. The system controller 110 is also coupled to one or more input devices 118, such as a keyboard or a mouse, to allow an operator to interface with the computer system 100. Typically, the computer system 100 also includes one or more output devices 120, such as a printer, coupled to the processor 104 through the system controller 110. One or more data storage devices 124 are also typically coupled to the processor 104 through the system controller 110 to allow the processor 104 to store data or retrieve data from internal or external storage media (not shown). Examples of typical storage devices 124 include hard and floppy disks, tape cassettes, and compact disk read-only memories (CD-ROMs).

The system controller 110 is coupled to several memory modules 130a,b . . . n, which serve as system memory for the computer system 100. The memory modules 130 are preferably coupled to the system controller 110 through a high-speed link 134, which is preferably a high-speed differential signal path through which at least one digital differential signal is coupled. However, other communications paths may also be used. The memory modules 130 are shown coupled to the system controller 110 in a point-to-point arrangement in which each segment of the high-speed link 134 is coupled between only two points. Therefore, all but the final memory module 130n is used as a conduit for memory requests and data coupled to and from downstream memory modules 130. However, it will be understood that other topologies may also be used. A switching topology may also be used in which the system controller 110 is selectively coupled to each of the memory modules 130 through a switch (not shown). Other topologies that may be used will be apparent to one skilled in the art.

Each of the memory modules 130 includes a memory hub 140 for controlling access to 16 memory devices 148, which, in the example illustrated in FIG. 3, are synchronous dynamic random access memory (“SDRAM”) devices. The memory hub 140 in all but the final memory module 130 also acts as a conduit for coupling memory commands to downstream memory hubs 140 and data to and from downstream memory hubs 140. However, a fewer or greater number of memory devices 148 may be used, and memory devices other than SDRAM devices 148 may, of course, also be used. The memory hub 140 is coupled to each of the system memory devices 148 through a bus system 150, which normally includes a control bus, an address bus and a data bus.

As explained in greater detail below, each of the memory hubs 140 include a signal amplitude threshold detector according to one example of the invention that detects the presence of digital signals coupled through the high-speed link 134. In response to detecting the presence of the digital signals, the signal amplitude threshold detector activates the memory hub 140 containing the peak detector. The use of a signal amplitude threshold detector allows the memory hub 140 to be activated responsive to very low amplitude digital signals and still not respond to noise that may be present on the high-speed link 134. Further, since the signal amplitude threshold detector does not transition until after its input signal has been reduced for a predetermined period, the memory hub 140 remains powered for a short period after a signal is no longer present on the high-speed link 134. As a result, the memory hub 140 can respond to the initial portion of a signal coupled through the high-speed link 134 if there is a short period of inactivity between signal transmissions.

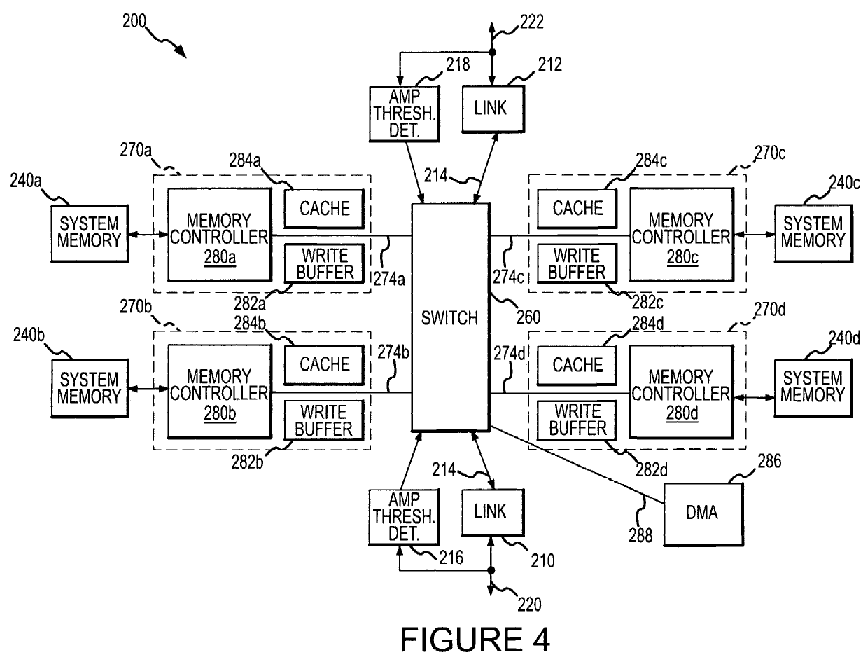

A memory hub 200 according to an example of the present invention is shown in FIG. 4. The memory hub 200 can be substituted for the memory hub 140 of FIG. 3. The memory hub 200 is shown in FIG. 4 as being coupled to four memory devices 240a-d, which, in the present example are conventional SDRAM devices. In an alternative embodiment, the memory hub 200 is coupled to four different banks of memory devices, rather than merely four different memory devices 240a-d, with each bank typically having a plurality of memory devices. However, for the purpose of providing an example, the present description will be with reference to the memory hub 200 coupled to the four memory devices 240a-d. It will be appreciated that the necessary modifications to the memory hub 200 to accommodate multiple banks of memory is within the knowledge of those ordinarily skilled in the art.

Further included in the memory hub 200 are link interfaces 210 and 212 for coupling the memory module on which the memory hub 200 is located to a first high speed data link 220 and a second high speed data link 222, respectively. The link interfaces 210 and 212 allow the memory hub 200 to be used as a conduit for memory requests and data to and from downstream memory modules 130. As previously discussed with respect to FIG. 3, the high speed data links 220, 222 are preferably signal lines through which digital differential signals are coupled. The link interfaces 210, 212 are conventional, and include circuitry used for transferring data, command, and address information to and from the high speed data links 220, 222. As is well known, such circuitry includes transmitter and receiver logic known in the art. It will be appreciated that those ordinarily skilled in the art have sufficient understanding to modify the link interfaces 210, 212 to be used with specific types of communication paths, and that such modifications to the link interfaces 210, 212 can easily be made.

The link interfaces 210, 212 are coupled to a switch 260 through a plurality of bus and signal lines, represented by busses 214. The busses 214 are conventional, and include a write data bus and a read data bus, although a single bi-directional data bus may alternatively be provided to couple data in both directions through the link interfaces 210, 212. It will be appreciated by those ordinarily skilled in the art that the busses 214 are provided by way of example, and that the busses 214 may include fewer or greater signal lines, such as further including a request line and a snoop line, which can be used for maintaining cache coherency.

The link interfaces 210, 212 include circuitry that allow the memory hub 200 to be connected in the system memory in a point-to-point configuration, as previously explained. This type of interconnection provides better signal coupling between the processor 104 and the memory hub 200 for several reasons, including relatively low capacitance, relatively few line discontinuities to reflect signals and relatively short signal paths. However, the link interfaces 210 and 212 could also be used to allow coupling to the memory hubs 200 in a variety of other configurations.

According to one example of the invention, the memory hub 200 includes signal amplitude threshold detectors 216, 218 coupled to the high-speed links 220, 222, respectively, and to the switch 260. The signal amplitude threshold detectors 216, 218 may be the signal amplitude threshold detector 10 of FIG. 1 or a signal amplitude threshold detector according to another example of the invention. The signal amplitude threshold detectors 216, 218 detect digital signals on the links 220, 222, respectively, and, in response thereto, apply a respective actuating signal to the switch 260. The switch 260 then enables the operation of the memory hub 200, and it may apply power to all or some of the components of the memory hub 200 from which power was removed when the memory hub 200 was inactive.

The switch 260 is further coupled to four memory interfaces 270a-d which are, in turn, coupled to the system memory devices 240a-d, respectively. The switch 260 coupling the link interfaces 210, 212 and the memory interfaces 270a-d can be any of a variety of conventional or hereinafter developed switches. By providing a separate and independent memory interface 270a-d for each system memory device 240a-d, respectively, the memory hub 200 avoids bus or memory bank conflicts that typically occur with single channel memory architectures. The switch 260 is coupled to each memory interface through a plurality of bus and signal lines, represented by busses 274. The busses 274 include a write data bus, a read data bus, and a request line. However, it will be understood that a single bi-directional data bus may alternatively be used instead of a separate write data bus and read data bus. Moreover, the busses 274 can include a greater or lesser number of signal lines than those previously described.

Each memory interface 270a-d may be specially adapted to the system memory devices 240a-d to which it is coupled. More specifically, each memory interface 270a-d may be specially adapted to provide and receive the specific signals received and generated, respectively, by the system memory device 240a-d to which it is coupled. Also, the memory interfaces 270a-d are capable of operating with system memory devices 240a-d operating at different clock frequencies. As a result, the memory interfaces 270a-d isolate the processor 104 from changes that may occur at the interface between the memory hub 230 and memory devices 240a-d coupled to the memory hub 200, and it provides a more controlled environment to which the memory devices 240a-d may interface.

With further reference to FIG. 4, each of the memory interfaces 270a-d includes a respective memory controller 280, a respective write buffer 282, and a respective cache memory unit 284. The memory controller 280 performs the same functions as a conventional memory controller by providing control, address and data signals to the system memory devices 240a-d to which it is coupled and receiving data signals from the system memory devices 240a-d to which it is coupled. The write buffer 282 and the cache memory unit 284 include the normal components of a buffer and cache memory, including a tag memory, a data memory, a comparator, and the like, as is well known in the art. The memory devices used in the write buffer 282 and the cache memory unit 284 may be either DRAM devices, static random access memory (“SRAM”) devices, other types of memory devices, or a combination of all three. Furthermore, any or all of these memory devices as well as the other components used in the cache memory unit 284 may be either embedded or stand-alone devices.

The write buffer 282 in each memory interface 270a-d is used to store write requests while a read request is being serviced. In such a system, the processor 104 can issue a write request to a system memory device 240a-d even if the memory device to which the write request is directed is busy servicing a prior write or read request. Using this approach, memory requests can be serviced out of order since an earlier write request can be stored in the write buffer 282 while a subsequent read request is being serviced. The ability to buffer write requests to allow a read request to be serviced can greatly reduce memory read latency since read requests can be given first priority regardless of their chronological order. For example, a series of write requests interspersed with read requests can be stored in the write buffer 282 to allow the read requests to be serviced in a pipelined manner followed by servicing the stored write requests in a pipelined manner. As a result, lengthy settling times between coupling write request to the memory devices 270a-d and subsequently coupling read request to the memory devices 270a-d for alternating write and read requests can be avoided.

The use of the cache memory unit 284 in each memory interface 270a-d allows the processor 104 to receive data responsive to a read command directed to a respective system memory device 240a-d without waiting for the memory device 240a-d to provide such data in the event that the data was recently read from or written to that memory device 240a-d. The cache memory unit 284 thus reduces the read latency of the system memory devices 240a-d to maximize the memory bandwidth of the computer system. Similarly, the processor 104 can store write data in the cache memory unit 284 and then perform other functions while the memory controller 280 in the same memory interface 270a-d transfers the write data from the cache memory unit 284 to the system memory device 240a-d to which it is coupled.

Further included in the memory hub 200 is a DMA engine 286 coupled to the switch 260 through a bus 288. The DMA engine 286 enables the memory hub 200 to move blocks of data from one location in the system memory to another location in the system memory without intervention from the processor 104. The bus 288 includes a plurality of conventional bus lines and signal lines, such as address, control, data busses, and the like, for handling data transfers in the system memory. Conventional DMA operations well known by those ordinarily skilled in the art can be implemented by the DMA engine 286. The DMA engine 286 is able to read a link list in the system memory to execute the DMA memory operations without processor intervention, thus, freeing the processor 104 and the bandwidth limited system bus from executing the memory operations. The DMA engine 286 can also include circuitry to accommodate DMA operations on multiple channels, for example, for each of the system memory devices 240a-d. Such multiple channel DMA engines are well known in the art and can be implemented using conventional technologies.

From the foregoing it will be appreciated that, although specific embodiments of the invention have been described herein for purposes of illustration, it will be understood by one skilled in the art that various modifications may be made without deviating from the spirit and scope of the invention. Accordingly, the invention is not limited except as by the appended claims.

What is claimed is:

1. A signal amplitude threshold detector, comprising:
a reference voltage generator providing a reference voltage having a predetermined amplitude;
a comparator having a first input coupled to receive an input signal and a second input coupled to receive the reference voltage from the reference voltage generator, the comparator being operable to generate a first logic level when the amplitude of the input signal is less than the amplitude of the reference voltage, and to generate a second logic level when the amplitude of the input signal is greater than the amplitude of the reference voltage;
a capacitor coupled between the first input of the comparator and a fixed circuit node; and
a resistor coupled between the first input of the comparator and the fixed circuit node.

2. The signal amplitude threshold detector of claim 1 wherein the fixed circuit node comprises a circuit ground node.

3. The signal amplitude threshold detector of claim 1, further comprising a diode coupled to the first input of the comparator, the diode being structured to couple the input signal to the first input of the comparator.

4. The signal amplitude threshold detector of claim 1 wherein the reference voltage generated by the reference voltage generator comprises a positive voltage.

5. An amplitude threshold detector for detecting when the peak amplitude of an input signal exceeds a predetermined amplitude threshold, the peak voltage detector comprising:
a reference voltage generator providing a reference voltage having a predetermined amplitude;
a comparator having a first input coupled to receive an input signal and a second input coupled to receive the reference voltage from the reference voltage generator, the comparator being operable to generate a first logic level when the amplitude of a voltage at its first input is less than the amplitude of the reference voltage, and to generate a second logic level when the amplitude of a voltage at its first input is greater than the amplitude of the reference voltage;
a capacitor coupled between the first input of the comparator and a fixed circuit node; and
a resistor coupled between the first input of the comparator and the fixed circuit node.

6. The amplitude threshold detector of claim 5 wherein the fixed circuit node comprises a circuit ground node.

7. The amplitude threshold detector of claim 5 wherein the peak voltage detector is operable to apply current to the capacitor responsive to the input signal having an amplitude that is greater than the output signal from the peak voltage detector thereby increasing the amplitude of the output signal to an amplitude corresponding to the amplitude of the input signal, the peak voltage detector further being operable to terminate supplying current to the capacitor responsive to the input signal having an amplitude that is less than the output signal from the peak voltage detector thereby allowing the capacitor to discharge through the resistor.

8. The amplitude threshold detector of claim 5 wherein the reference voltage generated by the reference voltage generator comprises a positive voltage.

9. A memory module, comprising:
a plurality of memory devices; and
a memory hub, comprising:
a link interface receiving an input signal corresponding to memory requests for access to memory cells in at least one of the memory devices;
a memory device interface coupled to the memory devices, the memory device interface being operable to couple memory requests to the memory devices for access to memory cells in at least one of the memory devices and to receive read data responsive to at least some of the memory requests; and
an activation circuit operable to generate an activation signal for activating the memory hub, the activation circuit comprising:
a reference voltage generator providing a reference voltage having a predetermined amplitude;
a comparator having a first input coupled to receive the input signal from the link interface and a second input coupled to receive the reference voltage from the reference voltage generator, the comparator being operable to generate the activation signal when the amplitude of a voltage at its first input is greater than the amplitude of the reference voltage;
a capacitor coupled between the first input of the comparator and a fixed circuit node; and
a resistor coupled between the first input of the comparator and the fixed circuit node.

10. The memory module of claim 9 wherein the fixed circuit node comprises a circuit ground node.

11. The memory module of claim 9, further comprising a diode coupled to the first input of the comparator, the input signal from the link interface being coupled to the first input of the comparator through the diode.

12. The memory module of claim 9 wherein the reference voltage generated by the reference voltage generator comprises a positive voltage.

13. A memory hub, comprising:
a link interface receiving an input signal corresponding to memory requests;
a memory device interface operable to output memory requests and to receive read data responsive to at least some of the memory requests; and
an activation circuit operable to generate an activation signal for activating the memory hub, the activation circuit comprising:
a reference voltage generator providing a reference voltage having a predetermined amplitude;
a comparator having a first input coupled to receive the input signal from the link interface and a second input coupled to receive the reference voltage from the reference voltage generator, the comparator being operable to generate the activation signal when the amplitude of a voltage at its first input is greater than the amplitude of the reference voltage;
a capacitor coupled between the first input of the comparator and a fixed circuit node; and
a resistor coupled between the first input of the comparator and the fixed circuit node.

14. The memory hub of claim 13 wherein the fixed circuit node comprises a circuit ground node.

15. The memory hub of claim 13, further comprising a diode coupled to the first input of the comparator, the input signal from the link interface being coupled to the first input of the comparator through the diode.

16. The memory hub of claim 13 wherein the reference voltage generated by the reference voltage generator comprises a positive voltage.

17. A processor-based system, comprising:
a central processing unit (“CPU”);
a system controller coupled to the CPU, the system controller having an input port and an output port;
an input device coupled to the CPU through the system controller;
an output device coupled to the CPU through the system controller;
a storage device coupled to the CPU through the system controller;
a plurality of memory modules, each of the memory modules comprising:
a plurality of memory devices; and
a memory hub, comprising:
a high-speed link coupled to the CPU through the system controller;
a link interface coupled to the high-sped link, the link interface receiving an input signal corresponding to memory requests for access to memory cells in at least one of the memory devices;
a memory device interface coupled to the memory devices, the memory device interface being operable to couple memory requests to the memory devices for access to memory cells in at least one of the memory devices and to receive read data responsive to at least some of the memory requests; and
an activation circuit operable to generate an activation signal for activating the memory hub, the activation circuit comprising:
a reference voltage generator providing a reference voltage having a predetermined amplitude;
a comparator having a first input coupled to receive the input signal from the link interface and a second input coupled to receive the reference voltage from the reference voltage generator, the comparator being operable to generate the activation signal when the amplitude of a voltage at its first input is greater than the amplitude of the reference voltage;
a capacitor coupled between the first input of the comparator and a fixed circuit node; and
a resistor coupled between the first input of the comparator and the fixed circuit node.

18. The processor-based system of claim 17 wherein the fixed circuit node comprises a circuit ground node.

19. The processor-based system of claim 17, further comprising a diode coupled to the first input of the comparator, the input signal from the link interface being coupled to the first input of the comparator through the diode.

20. The processor-based system of claim 17 wherein the reference voltage generated by the reference voltage generator comprises a positive voltage.

21. A method of generating an output signal indicative of an input signal exceeding a predetermined threshold, the method comprising:
quickly increasing the amplitude of a first signal when the amplitude of the input signal increases above the amplitude of the first signal so that the amplitude of the first signal becomes substantially equal to the amplitude of the input signal;
slowly decreasing the amplitude of the first signal when the amplitude of the input signal decreases below the amplitude of the first signal;
comparing the amplitude of the first signal to a reference voltage; and
generating the output signal when the amplitude of the first signal is greater than the reference voltage.

22. The method of claim 21 wherein the act of quickly increasing the amplitude of the first signal when the amplitude of the input signal increases above the amplitude of the first signal comprises:
providing a capacitor having a terminal on which the first signal is generated;
directing current to the terminal of the capacitor when the amplitude of the input signal is above the amplitude of the first signal, thereby increasing the amplitude of the first signal; and
discontinuing directing current to the terminal of the capacitor when the amplitude of the first signal has increased to the amplitude of the input signal.

23. The method of claim 22 wherein the act of slowly decreasing the amplitude of the first signal when the amplitude of the input signal decreases below the amplitude of the first signal comprises slowly discharging the capacitor when the amplitude of the input signal decreases below the amplitude of the first signal, thereby decreasing the amplitude of the first signal.

24. The method of claim 23 wherein the act of discharging the capacitor when the amplitude of the input signal decreases below the amplitude of the first signal, thereby decreasing the amplitude of the first signal comprising coupling the capacitor in parallel with a resistor.

25. The method of claim 21 wherein the reference voltage comprises a positive voltage.
